(19) United States
(12) Patent Application Publication
(10) Pub. No.: US 2014/0170899 A1
(43) Pub. Date: Jun. 19, 2014

(54) JUMPER ASSEMBLY

(71) Applicants: HONG FU JIN PRECISION INDUSTRY (ShenZhen) CO., LTD., (US); HON HAI PRECISION INDUSTRY CO., LTD., New Taipei (TW)

(72) Inventors: WEI PANG, Shenzhen (CN); AI-LING HE, Shenzhen (CN); JUN-HUI WANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/727,538

(22) Filed: Dec. 26, 2012

(30) Foreign Application Priority Data
Dec. 13, 2012 (CN) 201210537270.7

(51) Int. Cl. H05K 1/02

(52) U.S. Cl. CPC H05K 1/0213
USPC 439/507

(57) ABSTRACT

A jumper assembly includes a connector and a jumper. The connector includes a main body, and a number of pins attached to the main body and arranged in a row. The jumper is slidably mounted to the connector. The jumper includes a conductive tab on a bottom of the jumper. When the jumper is slid to allow opposite ends of the conductive tab to abut two neighboring pins, the conductive tab electrically connects the neighboring pins. The jumper may slid be to a position where no pins are electrically connected to each other.

### BACKGROUND

1. Technical Field

The present disclosure relates to a jumper assembly.

2. Description of Related Art

Jumpers are generally used to connect connector pins together such as on a motherboard of a computer. The jumpers need to be removed from the connector or plugged in the connector frequently. Because the jumpers are very small, and once removed, they may be lost or misplaced and cannot easily be retrieved.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a jumper assembly, wherein the jumper assembly includes a jumper.

FIG. 2 is an enlarged view of a circled portion II of FIG. 1.

FIG. 3 is an enlarged, inverted view of the jumper of FIG. 1.

FIG. 4 is an assembled, isometric view of FIG. 1.

FIG. 5 is a cross-sectional view taken along the line V-V of FIG. 4.

FIG. 6 is an enlarged view of a circled portion VI of FIG. 5.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

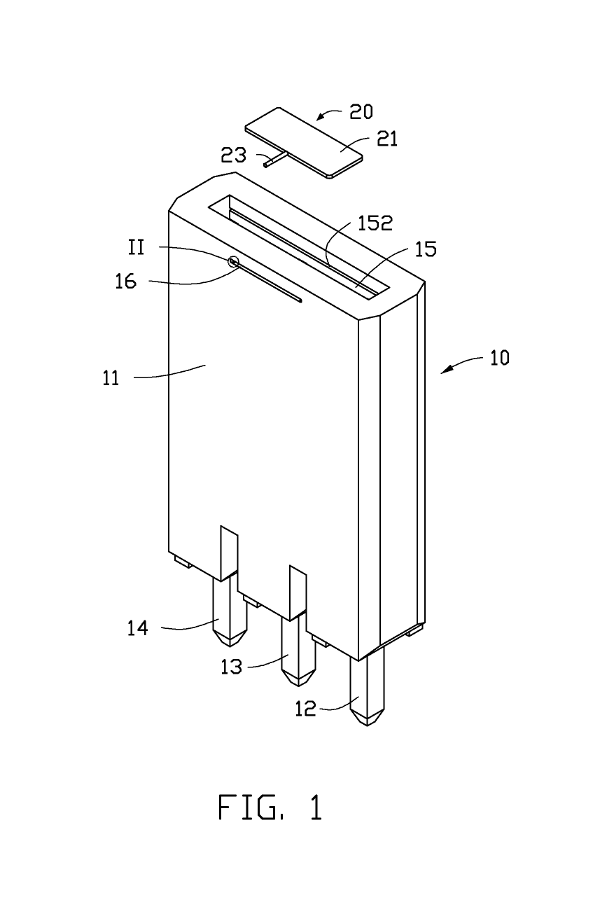

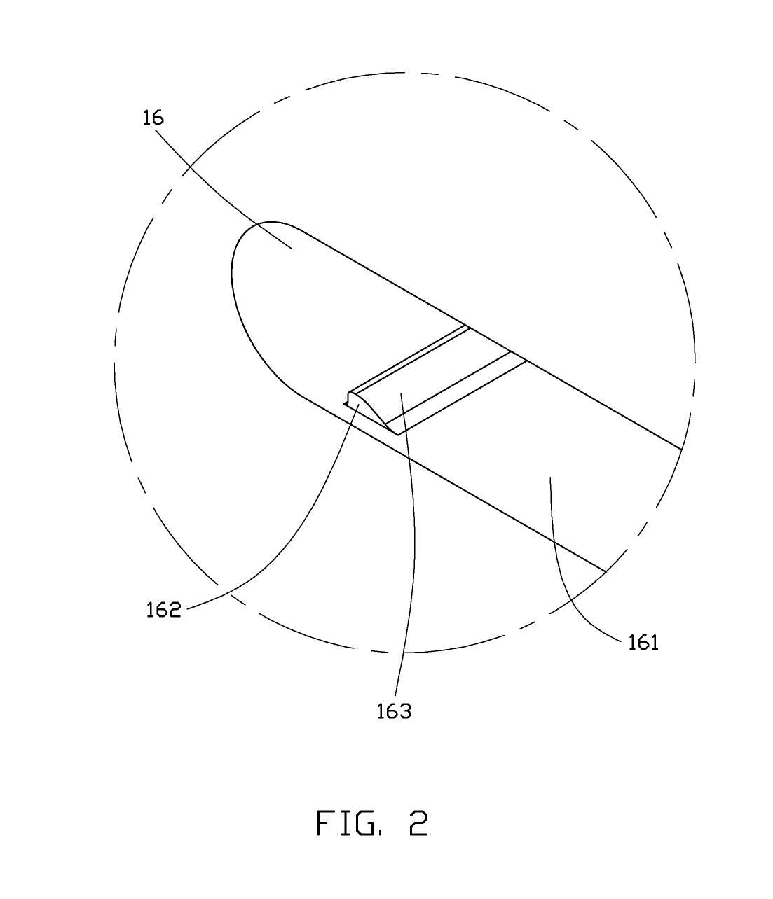

FIGS. 1 and 2 show an exemplary embodiment of a jumper assembly. The jumper assembly includes a connector 10 and a jumper 20.

The connector 10 includes a main body 11. The main body 11 defines a recess 15 extending through a top surface of the main body 11, a through slot 16 extending through a front side of the main body 11 and communicating with the recess 15, and a sliding slot 152 communicating with a rear side of the recess 15 and aligning with the through slot 16. A first pin 12, a second pin 13, and a third pin 14 are orderly attached to the main body 11, and arranged in a row. Upper portions of the first pin 12, the second pin 13, and the third pin 14 are received in the recess 15. Two protrusions 162 respectively protrude from top and bottom walls 161 bounding the through slot 16, near each end of the through slot 16. A slanting guiding surface 163 is formed on a side of each protrusion 162 facing a middle of the through slot 16.

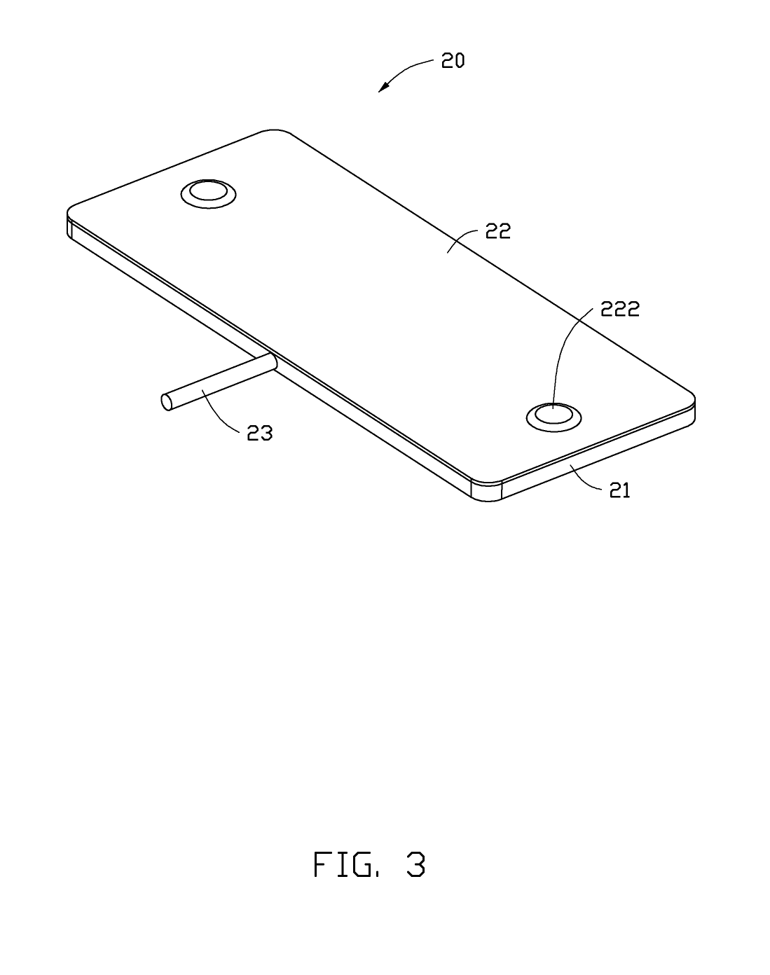

FIG. 3 shows the jumper 20 including a plate 21, a conductive tab 22 attached to a bottom surface of the plate 21, and a handle 23 extending from a middle of a side of the plate 21. Two contacting portions 222 protrude from opposite ends of a bottom surface of the conductive tab 22.

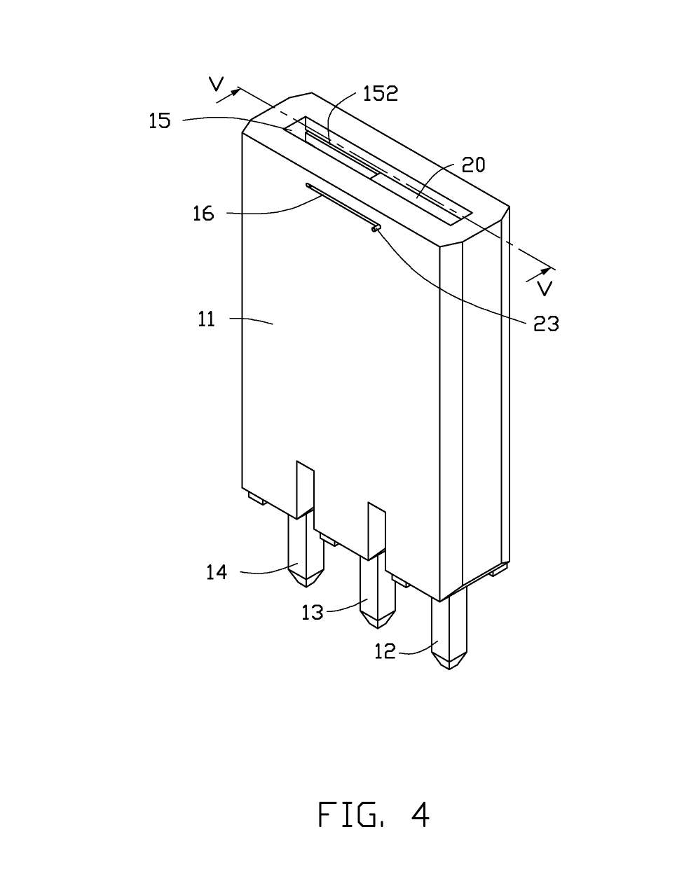

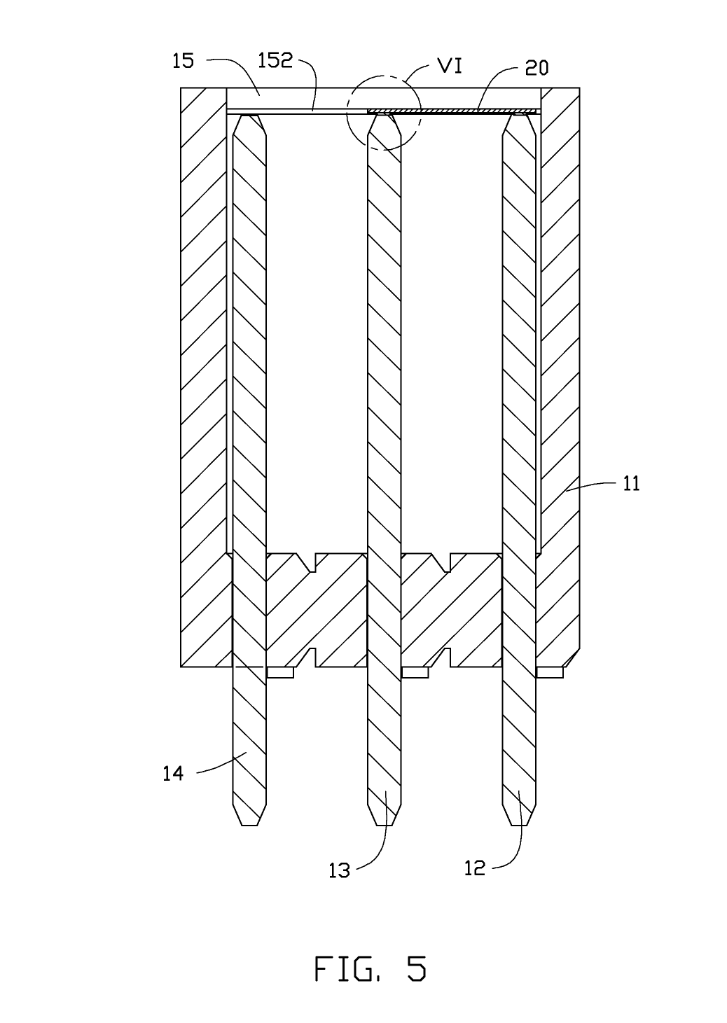

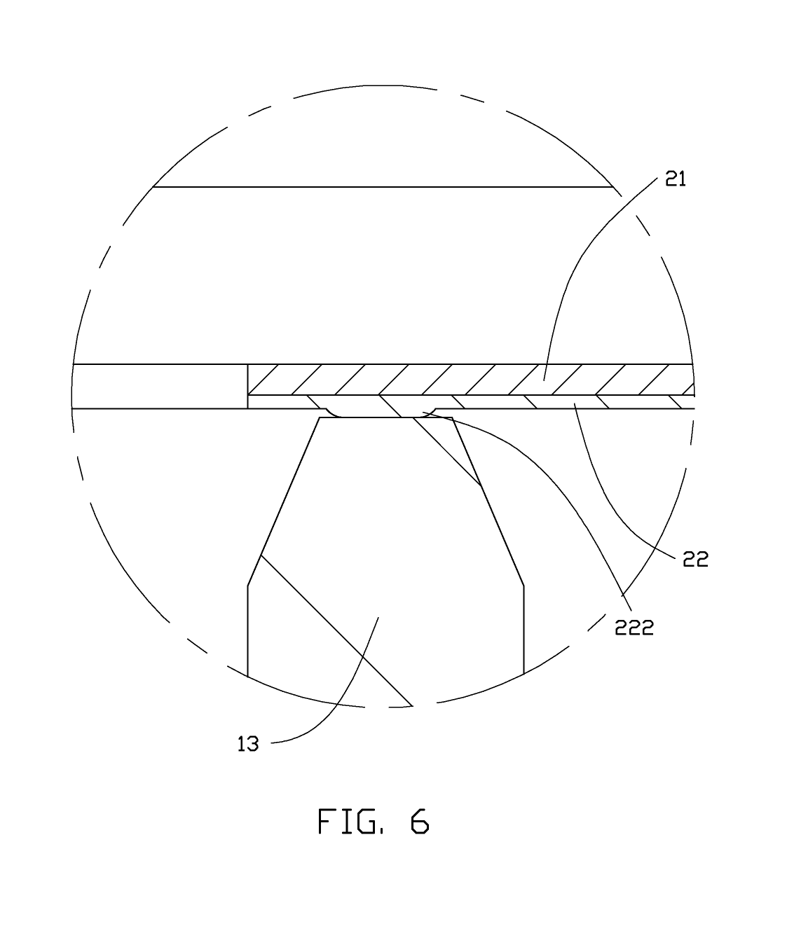

Shown in FIGS. 4-6, in use, the jumper 20 is inserted into the through slot 16, to allow the plate 21 and the conductive tab 22 to be supported on the bottom wall 161 and a bottom wall bounding the sliding slot 152. The handle 23 is extended out of the through slot 16 and located at the middle of the through slot 16. A middle of the conductive tab 22 abuts the second pin 13, and the conductive tab 22 do not abuts the first pin 12 and the third pin 14. In this connection no two pins are connected to each other. To electrically connect the first and second pins 12, 13 together, the handle 23 is manipulated to move toward the first pin 12 along the through slot 16. The handle 23 deforms the protrusions 162 near the first pin 12 to pass by the protrusions 162, thereby moving to the end of the through slot 16 adjacent to the first pin 12. The contacting portions 222 respectively abut the first pin 12 and the second pin 13, to electrically connect the first pin 12 to the second pin 13. The guiding surfaces 163 can guide the handle 23 to easily pass by the protrusions 162. To electrically connect the second and third pins 13, 14 together, the handle 23 is manipulated toward the third pin 14. The handle 23 deforms the protrusions 162 near the third pin 14 to pass by the protrusions 162, thereby moving to the end of the through slot 16 adjacent to the third pin 14. The contacting portions 222 respectively abut the second pin 13 and the third pin 14, to electrically connect the second pin 12 to the third pin 14. The jumper 20 is slidable relative to the connector 10, and need not be removed when none of the first, second and third pins 12, 13, 14 need to be electrically connected together. Therefore, the jumper 20 will not be lost.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A jumper assembly, comprising:
a connector comprising a main body, and a plurality of pins attached to the main body and arranged in a row; and
a jumper slidably mounted to the connector, the jumper comprising a conductive tab on a bottom of the jumper;
wherein when the jumper slides to allow opposite ends of the conductive tab to abut two neighboring pins, the conductive tab electrically connects the neighboring pins, and when the jumper slides to allow a middle of the conductive tab to abut one of the pins, the conductive tab does not abuts any other pin.

2. The jumper assembly of claim 1, wherein the main body defines a recess, a through slot and a sliding slot both communicating with the recess and located at opposite sides of the recess, upper portions of the pins are received in the recess, the jumper is slid along the through slot and the sliding slot.

3. The jumper assembly of claim 2, wherein the jumper comprises a handle extended out of the connector through the through slot.

4. The jumper assembly of claim 3, wherein the number of the pins is three, two protrusions respectively protrude from top and bottom walls bounding the through slot, near each end of the through slot, when the handle is located at a middle of the through slot, the conductive tab abuts the middle pin, but does not abut the two pins located at opposite ends of the connector, when the handle moves toward an end of the through slot, the handle passes by a space between the corresponding protrusions by deforming the corresponding protrusions, the opposite ends of the conductive tab abut the middle pin and the pin located at the corresponding end of the connector.

5. The jumper assembly of claim 4, wherein a slanting guiding surface is formed on a side of each protrusion facing a middle of the through slot.

6. The jumper assembly of claim 1, wherein two contacting portions protrude from the opposite ends of the conductive tab to abut the neighboring pins.
